(19) United States
(12) Patent Application Publication
(10) Pub. No.: US 2010/0047985 A1
(43) Pub. Date: Feb. 25, 2010

(54) METHOD FOR FABRICATING A SEMICONDUCTOR DEVICE WITH SELF-ALIGNED STRESSOR AND EXTENSION REGIONS

(75) Inventors: Srikanteswara DAKSHINA MURTHY, Singapore (SG); Martin GERHARDT, Dresden (DE)

Correspondence Address: Ingrassia Fisher & Lorenz, P.C. (GF), 7010 E. Cochise Rd., Scottsdale, AZ, 85253, US

(73) Assignee: ADVANCED MICRO DEVICES, INC., Austin, TX (US)

(21) Appl. No.: 12/194,246

(22) Filed: Aug. 19, 2008

(51) Int. Cl. H01L 21/336

(52) U.S. Cl. 438/303; 257/E21.64

(57) ABSTRACT

Methods are provided for fabricating a MOS transistor having self-aligned stressor and extension regions. A method comprises forming a gate stack overlying a layer of semiconductor material and forming a spacer about sidewalls of the gate stack. The method further comprises forming cavities in the layer of semiconductor material, wherein the cavities are substantially aligned with the spacer. The method further comprises forming a stress-inducing semiconductor material in the cavities, and implanting ions of a conductivity-determining impurity type into the stress-inducing semiconductor material using the gate stack and the spacer as an implantation mask.

### TECHNICAL FIELD

The present disclosure generally relates to semiconductor devices and methods for fabricating semiconductor devices, and more particularly, embodiments of the subject matter relate to methods for fabricating transistors having extension implants that are self-aligned with embedded stressor regions.

### BACKGROUND

The majority of present day integrated circuits (ICs) are implemented by using a plurality of interconnected field effect transistors (FETs) realized as metal oxide semiconductor field effect transistors (MOSFETs or MOS transistors). A MOS transistor includes a gate electrode as a control electrode that is formed on a semiconductor substrate and spaced-apart source and drain regions formed within the semiconductor substrate and between which a current can flow. A control voltage applied to the gate electrode controls the flow of current through a channel in the semiconductor substrate between the source and drain regions beneath the gate electrode. The MOS transistor is accessed via conductive contacts formed on the source and drain regions.

ICs are usually formed using both P-channel FETs (PMOS transistors) and N-channel FETs (NMOS transistors), referred to as a complementary MOS or CMOS integrated circuit. In sub-90 nm CMOS technologies, selective epitaxy is often used to increase the mobility of carriers in the channels of the MOS transistors. This is accomplished by etching a recess or cavity into the semiconductor substrate at the ends of the channel. The cavity may then be filled by the process of selective epitaxial growth with a crystalline material that has a different lattice constant than the host semiconductor substrate. For example, in a PMOS transistor formed on a silicon substrate, the cavity may be filled with silicon germanium (SiGe) to form stressor regions (e.g., embedded SiGe stressors), which apply a compressive longitudinal stress to the channel and increases the mobility of holes in the channel.

As the distance between the stressor regions to the channel decreases, the stress transferred to the channel increases, leading to improved performance at closer proximities. Often, a disposable deposited spacer (DDS) is formed about the sidewalls of the gate electrode and used to control the proximity of the stressor regions to the channel during the selective growth process. The spacer is usually removed following the selective epitaxy, and a second spacer (e.g., an offset spacer) is formed afterwards to define the placement of subsequent extension implanted regions.

Variations in the offset spacer boundary relative to the boundary of the stressor regions can have negative effects on device characteristics. For example, in a PMOS transistor, the diffusion rate of boron in silicon germanium is different than the diffusion rate of boron in silicon. Thus, any variation in the offset spacer boundary relative to the boundary of the stressor regions will affect the amount of lateral P-extension diffusion and the ensuing PMOS transistor source/drain extension overlap, caused by a combination of the as-implanted P-extension dopant profile (influenced by the offset spacer boundary), and the effective P-extension dopant diffusion into the channel (influenced by the extent of diffusion through the material under the offset spacer). Additionally, variations in the thickness of the stressor regions at different locations across the chip and/or wafer also influence the step coverage or etched profile of the offset spacer, and result in further variation in the offset spacer boundary across the chip and/or wafer. These variations affect transistor parameters, such as threshold voltage, drive current, and Miller capacitance. Non-uniformity across the chip and/or wafer can potentially affect the yield, performance, and minimum operating voltage characteristics of the chip and/or wafer.

As the stressor regions are formed closer to the channel, it becomes difficult to align the offset spacer with the boundary of the stressor regions. For example, in 45 nm or 32 nm technologies, the proximity of the stressor regions to the channel (alternatively, the thickness of the DDS) is often 10 nm or less. Because the DDS and the offset spacer are formed using separate deposition and etch processes, it is difficult to align the offset spacer with the boundary of the stressor regions. Additionally, in CMOS devices, the offset spacer is often used as an ion implantation mask during creation of extension implants for both the PMOS and NMOS transistor devices, which limits the ability to resize the offset spacer thickness for purposes of aligning the source/drain extensions for only one of the transistors. Some methods attempt to control the process uniformity of the deposition and etch processes for creating the spacers. However, these approaches add complexity and cost and still provide an imperfect solution.

### BRIEF SUMMARY

A method is provided for fabricating a MOS transistor. The method comprises forming a gate stack overlying a layer of semiconductor material and forming a spacer about sidewalls of the gate stack. The method further comprises forming cavities in the layer of semiconductor material, wherein the cavities are substantially aligned with the spacer. The method further comprises forming a stress-inducing semiconductor material in the cavities, and implanting ions of a conductivity-determining impurity type into the stress-inducing semiconductor material using the gate stack and the spacer as an implantation mask.

Another method is provided for fabricating a semiconductor device having stressor regions that are self-aligned with an ion implantation mask. The method comprises forming a gate stack overlying a layer of semiconductor material and forming a layer of an insulating material on the gate stack and the layer of semiconductor material. The method further comprises etching the layer of the insulating material and the layer of semiconductor material to form a spacer about sidewalls of the gate stack and cavities in the layer of semiconductor material, wherein the cavities are self-aligned with the spacer. The method further comprise forming a stress-inducing semiconductor material in the cavities, resulting in stressor regions that are self-aligned with the spacer, and implanting ions of a conductivity-determining impurity type into the stressor regions using the gate stack and the spacer as an implantation mask.

In another embodiment, a method for fabricating a CMOS device is provided. The method comprises providing a semiconductor device structure having a first region of semiconductor material and a second region of semiconductor material, a first gate stack overlying the first region of semiconductor material, and a second gate stack overlying the second region of semiconductor material. The method further comprises masking the second region of semiconductor material. While the second region of semiconductor material is masked, the method further comprises forming a spacer about sidewalls of the first gate stack, and forming cavities in the first region of semiconductor material, wherein the cavities are substantially aligned with the spacer. The method further comprises at least partially filling the cavities with a stress-inducing semiconductor material, and implanting P-type ions into the stress-inducing semiconductor material using the first gate stack and the spacer as an implantation mask.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIGS. 1-12 illustrate, in cross section, a CMOS semiconductor device structure and exemplary methods for fabricating the CMOS semiconductor device.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

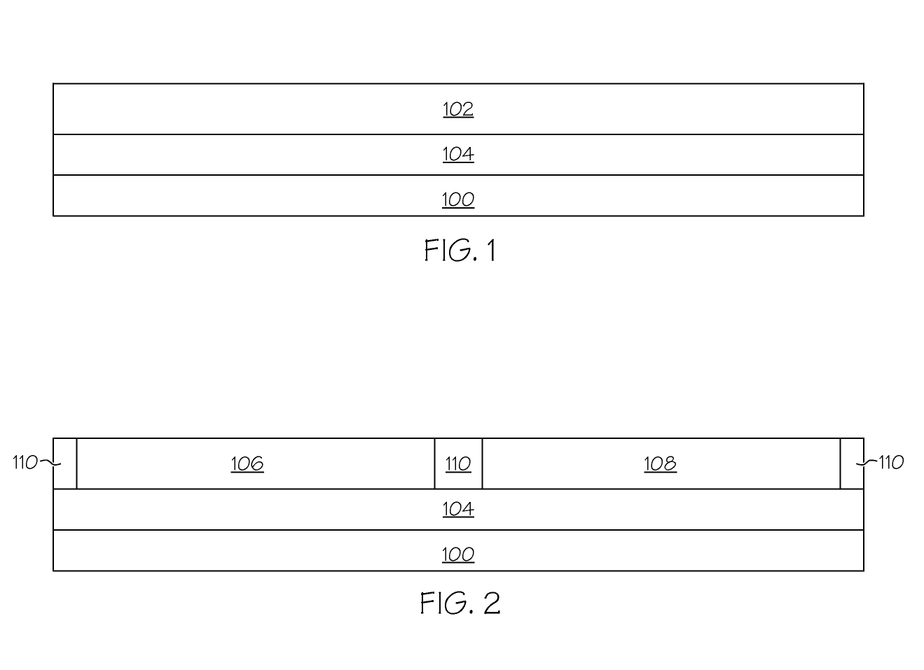

FIGS. 1-12 illustrate, in cross section, methods for fabricating a CMOS semiconductor device in accordance with exemplary embodiments. Various steps in the manufacture of MOS components are well known and so, in the interest of brevity, many conventional steps will only be mentioned briefly herein or will be omitted entirely without providing the well known process details. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

Referring to FIG. 1, the illustrated fabrication process begins by providing an appropriate semiconductor substrate having a layer of semiconductor material 102. The semiconductor material 102 is preferably a silicon material, wherein the term “silicon material” is used herein to encompass the relatively pure silicon materials typically used in the semiconductor industry as well as silicon admixed with other elements such as germanium, carbon, and the like. Alternatively, the semiconductor material 102 can be germanium, gallium arsenide, or the like. The semiconductor substrate may hereinafter be referred to for convenience, but without limitation, as a silicon substrate. In an exemplary embodiment, the semiconductor substrate is realized as silicon-on-insulator (SOI) substrate having a support layer 100, a layer of insulating material 104 on the support layer 100, and the layer of semiconductor material 102 on the layer of insulating material 104. The insulating material 104 is preferably realized as an oxide layer formed in a subsurface region of the semiconductor substrate, also known as a buried oxide (BOX) layer. For example, the layer of insulating material 104 may be formed by an ion implantation process followed by high temperature annealing to create a buried layer of silicon dioxide (SiO₂). Depending on the embodiment, the thickness of the semiconductor material 102 may range from about 20 nm to 150 nm and the thickness of the insulating material 104 may range from about 50 nm to 200 nm. These thicknesses are based on factors such as the nature of the SOI device (fully or partially depleted body) and the processes used to create the SOI substrate. It should be understood that the fabrication process described herein is not constrained by the dimensions of the semiconductor material 102 or the insulating material 104. Further, it should be appreciated that the fabrication process described below may also be used to create devices from a bulk semiconductor substrate.

As shown in FIG. 2, in an exemplary embodiment, the semiconductor substrate is used to fabricate a CMOS device by forming electrically isolated regions 106, 108 in the semiconductor material 102. The isolated regions 106, 108 may be formed by shallow trench isolation (STI), local oxidation of silicon (LOCOS), or another suitable process known in the art. Preferably, the regions 106, 108 are formed by performing shallow trench isolation on the semiconductor substrate by etching trenches into the surface of the semiconductor material 102 and forming a layer of insulating material 110 in the trench. In an exemplary embodiment, the trenches are etched to a depth at least equal to the thickness of the layer of semiconductor material 102 overlying the insulating layer 104. Preferably, a layer of oxide is formed in the trench, known as the field oxide. The insulating material 110 may hereinafter be referred to for convenience, but without limitation, as the field oxide.

In a preferred embodiment, the isolated regions 106, 108 are implanted with ions to achieve a desired dopant profile. For example, a layer of photoresist may be applied and patterned to mask the first region 106, and a P-well may be formed in the second region 108 by implanting the second region 108 with boron ions. The layer of photoresist masking the first region 106 may be removed, and another layer of photoresist applied and patterned to mask the second region 108. An N-well may be formed in the first region 106 by implanting arsenic and/or phosphorus ions into the first region 106. The layer of photoresist masking the second region 108 is removed and the semiconductor substrate is heated to activate the implants. These ion implantation steps may include several different, separate implantations at different energies and different doses to achieve a desired doping profile, as will be appreciated in the art.

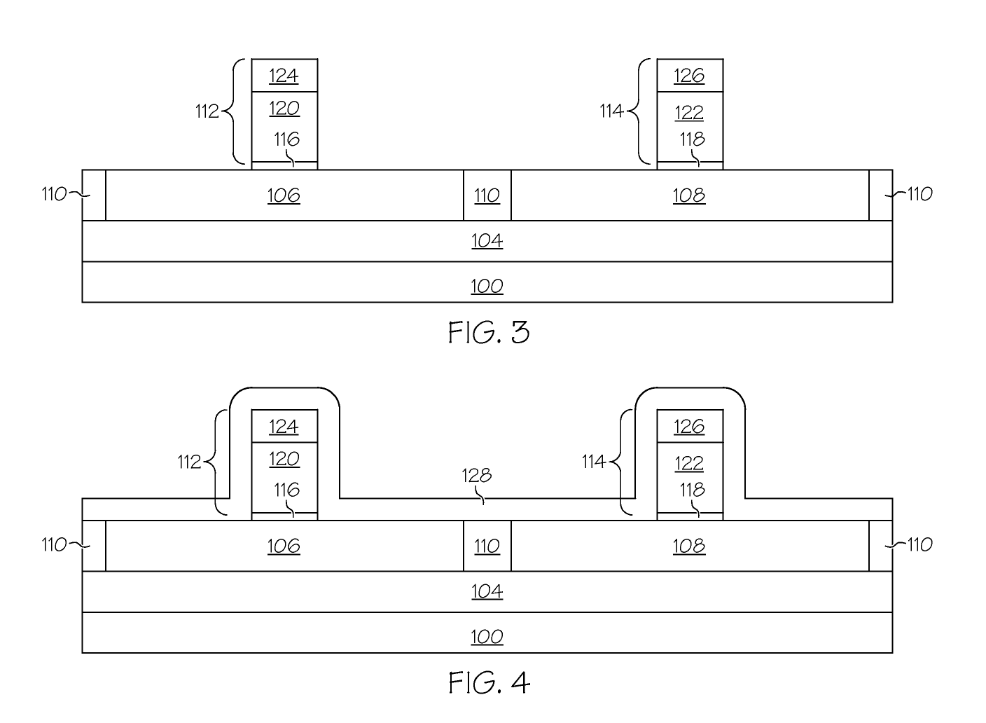

Referring to FIG. 3, the fabrication process continues by forming gate stacks 112, 114 overlying the isolated regions 106, 108 for creating MOS transistors about the respective regions 106, 108. In conventional processing, a gate insulator material is formed overlying the isolated regions 106, 108 and the field oxide 110 for purposes of forming gate insulators 116, 118. The layer of gate insulating material can be a layer of thermally grown silicon dioxide or, alternatively, a deposited insulator such as a silicon oxide, silicon nitride, or the like. A layer of gate electrode material is formed overlying the gate insulating material for purposes of forming gate electrodes 120, 122. In accordance with one embodiment, the gate electrode material is polycrystalline silicon. The layer of polycrystalline silicon is preferably deposited as undoped polycrystalline silicon. The polycrystalline silicon can be deposited by low-pressure chemical vapor deposition (LPCVD) by the hydrogen reduction of silane. In an exemplary embodiment, the gate stacks 112, 114 may also include a gate cap 124, 126 formed from a layer of insulating material deposited onto the surface of the polycrystalline silicon. Preferably, this layer of insulating material is realized as silicon nitride with a thickness of about 30 to 60 nm. The insulating layer, underlying gate electrode material layer, and gate insulating material layer are patterned and etched to form gate stacks 112, 114, each having a respective gate insulator 116, 118, gate electrode 120, 122, and gate cap 124, 126 as illustrated in FIG. 3.

Referring to FIG. 4, the fabrication process continues by forming a layer of insulating material 128 overlying the gate stacks 112, 114, isolated regions 106, 108 and field oxide 110. The insulating material may be, for example, a nitride (preferably silicon nitride (Si₃N₄)), and it may be conformally deposited in a known manner by, for example, atomic layer deposition (ALD), chemical vapor deposition (CVD), LPCVD, sub-atmospheric chemical vapor deposition (SACVD), or plasma-enhanced chemical vapor deposition (PECVD). The insulating layer 128 is preferably deposited to a thickness no greater than about 10 nm, although in practice, the thickness of the insulating layer 128 may be increased up to about 20 nm as needed.

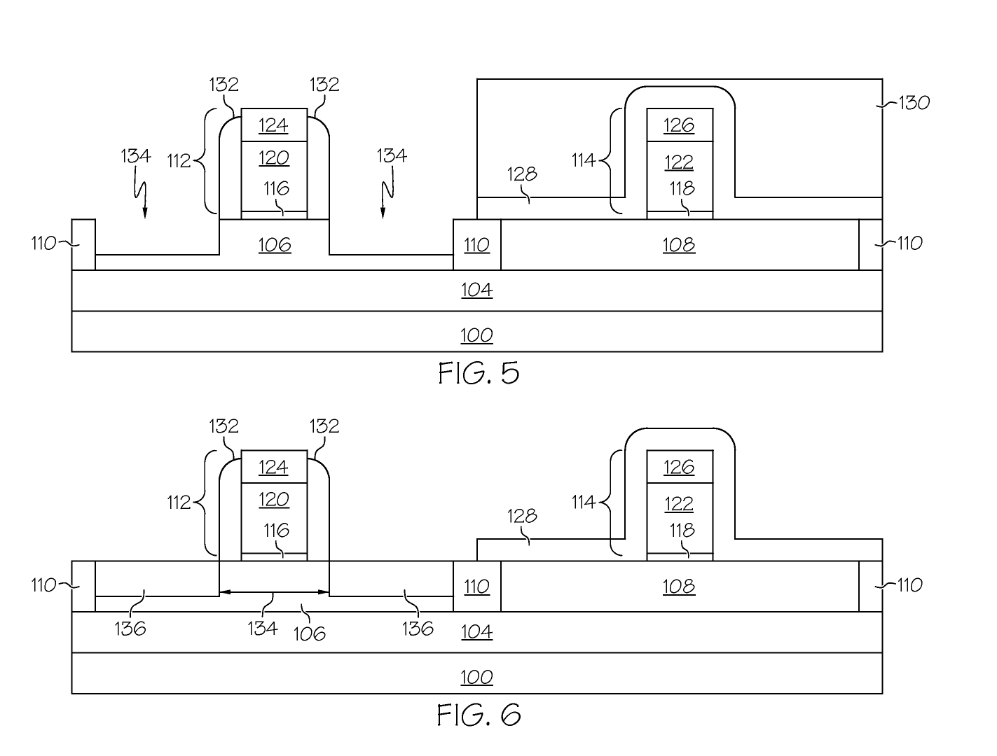

Although one or more additional process steps may be performed next, in a preferred embodiment, the fabrication of the CMOS semiconductor device continues by forming a PMOS transistor structure on the first region 106 of the semiconductor substrate, as shown in FIGS. 5-8 and described in greater detail below. It should be understood that although FIGS. 5-8 are described herein in the context of a PMOS implementation, the process described herein may be implemented for forming a NMOS transistor structure in a like manner, as will be appreciated by those skilled in the art.

In an exemplary embodiment, the second region 108 and gate stack 114 are masked by depositing and patterning photoresist material to leave a layer of photoresist 130 that protects the second region 108 and gate stack 114 as illustrated in FIG. 5. Notably, photoresist 130 does not cover any portion of the first region 106; in the illustrated embodiment, the edge of the photoresist 130 overlaps at least part of the field oxide 110. In an exemplary embodiment, the process continues by forming a spacer 132 about the sidewalls of the gate stack 112. The spacer 132 is preferably formed by anisotropically etching the insulating layer 128 using processes well known in the art. For example the spacer 132 formed from a silicon nitride material may be created using plasma-based RIE (reactive ion etching), using commonly known etchant chemistries such as, for example, CF₄+O₂, CHF₃+O₂, CH₂F₂+CF₄+O₂, SF₆+HBr, or CF₄+HBr. The resultant spacer 132 or a width no greater than about 10 nm. This etching step selectively and anisotropically removes silicon-based material (i.e., the unprotected portion of insulating layer 128 overlying the field oxide 110, and the unprotected portion of insulating layer 128 overlying first region 106). In practice, the anisotropic etch may partially etch gate cap 124, and reduce the thickness of the gate cap 124 to between approximately 20 to 30 nm. In an exemplary embodiment, at least a portion of the gate cap 124 remains after the insulating layer 128 is etched to form the spacer 132.

In an exemplary embodiment, the fabrication process continues by forming cavities 134 in the layer of semiconductor material of first region 106. Notably, the cavities 134 are formed in the first region 106 by anisotropically etching the layer of semiconductor material using the gate stack 112, photoresist layer 130, and spacer 132 as an etch mask. In this manner, the cavities 134 are self-aligned with the spacer 132. As used herein, self-aligned should be understood to mean that the inward facing sides of the cavities 134 are naturally formed such that they are aligned with the outward facing sides of the spacers 132. This self-aligned characteristic is evident in FIG. 5, where it appears as though the vertical sidewalls of spacers 132 continue downward to form the corresponding inward facing sidewalls of the cavities 134. As described below, the regions of the cavities 134 substantially follow the exposed area of region 106, which is defined by the position and extent of the spacers 132, and thus, the cavities 134 can be thought of as self-aligned to these spacers 132.

In an exemplary embodiment, the spacer 132 and cavities 134 are preferably formed as part of the same overall etch process sequence, but using two distinct steps within that sequence for formation of the spacers 132, followed by formation of the cavities 134. For example, the cavities 134 in the silicon material of region 106 may be created using plasma-based RIE (reactive ion etching), using commonly known etchant chemistries such as, for example, Cl₂+HBr, HBr+O₂, or Cl₂+HBr+O₂, which have the advantage of etching silicon with good selectivity to the spacers 132, the gate cap 124, as well as the exposed field oxide region 110. In an exemplary embodiment, the cavities 134 are formed having a depth relative to the surface of the semiconductor material less than the thickness of the semiconductor material 102 such that the underlying insulating material 104 is not exposed. In a preferred embodiment, the cavities 134 are used to define the lateral boundaries of subsequently formed stressor regions. After forming the cavities 134, the second region 108 and gate stack 114 may be unmasked by removing the photoresist layer 130 in a conventional manner.

One or more intermediate process steps may be performed after formation of cavities 134. However, referring now to FIG. 6, in accordance with an exemplary embodiment, the process continues by forming a stress-inducing semiconductor material in the cavities 134 to form stressor regions 136. In a preferred embodiment, the stressor regions 136 are realized by forming the stress-inducing semiconductor material in the cavities 134. The stressor regions 136 may be formed by growing a crystalline material having a different lattice constant than the host semiconductor material 102 on the exposed surface of the semiconductor material of first region 106 (e.g., the exposed surfaces bordering the cavities 134). In an exemplary embodiment, the stressor regions 136 are formed by epitaxially growing a layer of stress-inducing semiconductor material in the cavities 134. In this regard, the spacer 132, gate cap 124, and insulating material 128 act as a mask (i.e., selective epitaxy) preventing any epitaxial growth on the surface of the gate electrode 120, first region 106 (other than that in the cavities 134), or second region 108. Preferably, the epitaxial layer is grown to at least the thickness of the cavities 134 (e.g., a “flush” fill or slight overfill). In an exemplary embodiment, for a PMOS transistor, the stressor regions 136 are realized as epitaxial silicon germanium (SiGe), alternatively referred to as embedded SiGe. The silicon germanium is preferably undoped or “early” silicon germanium. The embedded SiGe stressor regions 136 apply a compressive longitudinal stress to the channel, which increases the mobility of holes in the channel. Similarly, for an NMOS implementation, the mobility of electrons in the channel can be increased by applying a tensile longitudinal stress to the channel by embedding a material having a smaller lattice constant than the host silicon substrate, such as monocrystalline carbon silicon (CSi), as is known in the art.

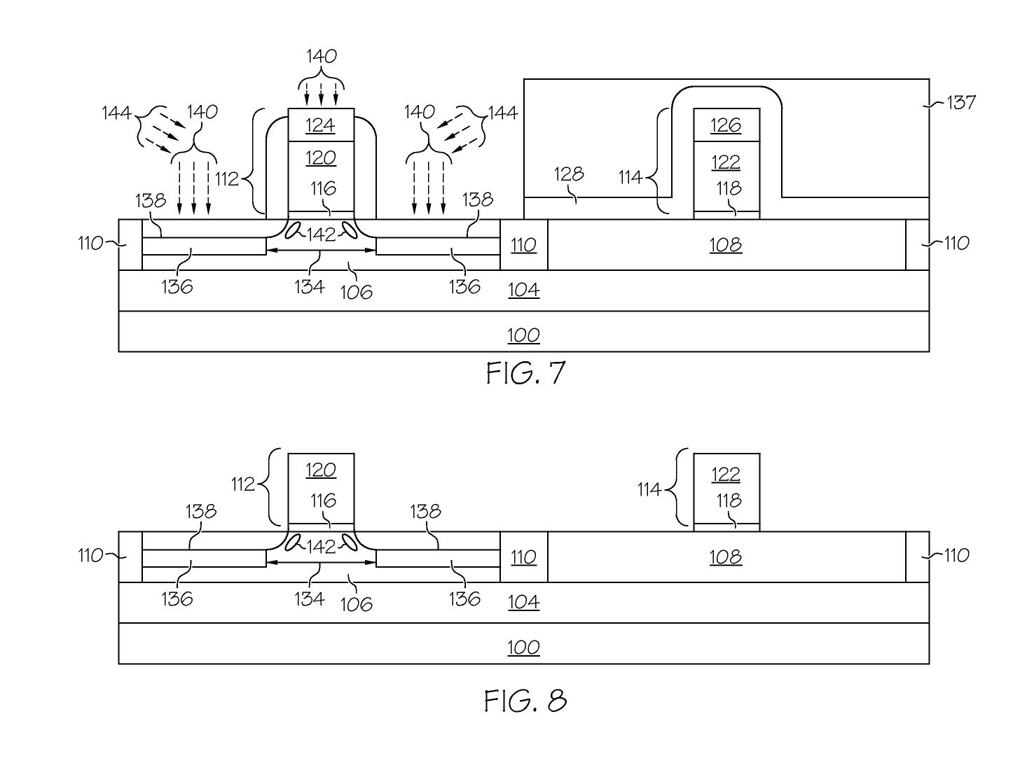

Referring now to FIG. 7, in an exemplary embodiment, the second region 108 and gate stack 114 are masked by depositing and patterning photoresist material to leave a layer of photoresist 137 that protects the second region 108 and gate stack 114 in a manner similar to that described above. In an exemplary embodiment, the fabrication process continues by forming spaced-apart source and drain extensions 138 by appropriately impurity doping the stressor regions 136 in a known manner, for example, by ion implantation of dopant ions, illustrated by arrows 140, and subsequent thermal annealing. Preferably, the source and drain extensions 138 are formed by implanting ions of a conductivity-determining impurity type into the stressor regions 136 using the gate stack 112, spacer 132, photoresist layer 137, and field oxide 110 as an implantation mask. For a P-channel device, the source and drain extensions are formed by implanting P-type ions, preferably boron fluoride (BF₂⁺) ionized species or boron ions. The source and drain extensions 138 are shallow and preferably have a junction depth of about 10 to 20 nm and are typically impurity doped to a sheet resistivity of about 400-1000 ohms per square. By using the gate stack 112 and spacer 132 as an ion implant mask, the ion implant boundaries are self-aligned with the stressor regions 136, due to the orthogonal orientation of ions 140 with respect to a surface of the semiconductor material 102. In this regard, the spacer 132 controls the proximity to the channel for both the stressor regions 136 (e.g., cavities 134) and the source and drain extensions 138, because the extent of the source and drain extensions 138 depends on the diffusion rate of the dopant ions in the stressor regions 136. In practice, the gate cap 124 may prevent doping of the gate electrode 120 during the shallow source and drain extension implants 140, however, the gate electrode 120 can be sufficiently doped as part of a subsequent fabrication process, for example, during the deeper ion implantation steps for the source/drain junction formation.

In a preferred embodiment, the gate stack 112, spacer 132, photoresist layer 137, and field oxide 110 are also used as an ion implantation mask to form halo implants 142 by appropriately impurity doping the first region 106 in known manner. The halo implants 142 are preferably formed by implanting ions of the same conductivity-determining impurity type as the channel for the first region 106. For a PMOS transistor, the halo implants 142 are formed by implanting N-type ions, preferably arsenic ions, although phosphorus ions could also be used. The halo implants 142 are formed at an angle relative to the surface of the semiconductor device, for example, by ion implantation of dopant ions at an angle, illustrated by arrows 144, and subsequent thermal annealing. Preferably, the angle of implantation is between 20° and 50° relative to the surface normal of the semiconductor device. After forming the source and drain extensions 138 and halo implants 142, the second region 108 and gate stack 114 may be unmasked by removing the photoresist layer 137 in a conventional manner. In a preferred embodiment, after removing the photoresist layer 137, the spacer 132 and gate cap 124 are removed using a single hot phosphoric acid (H₃PO₄) etchant process. Since the entire wafer is exposed to the etchant chemical, this also results in simultaneous removal of the remaining insulating layer 128 and gate cap 126, eventually leading to the structure as shown in FIG. 8.

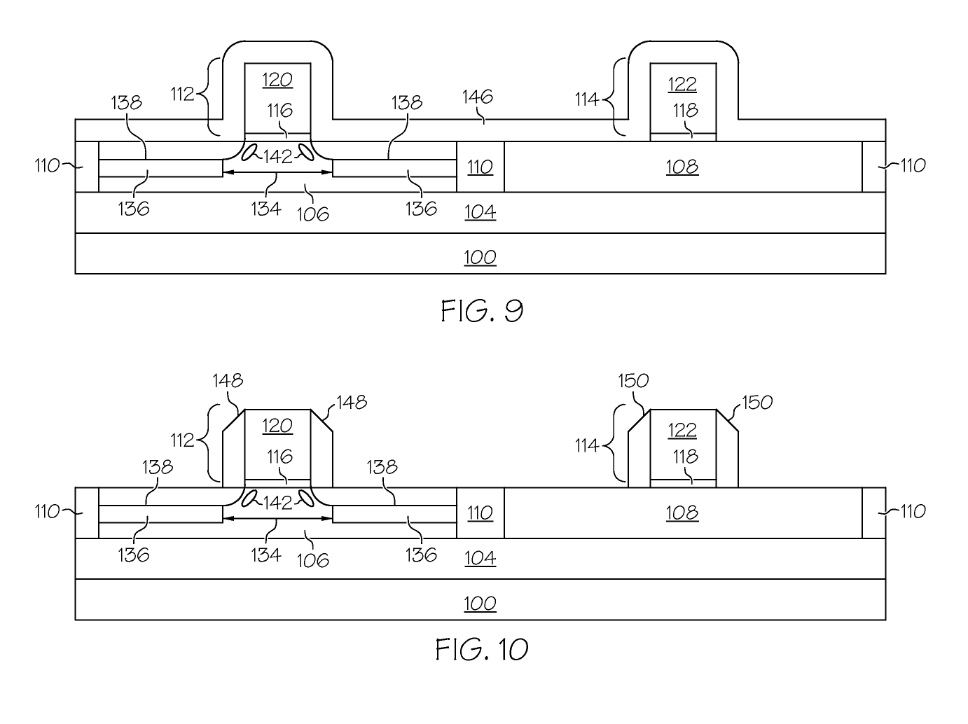

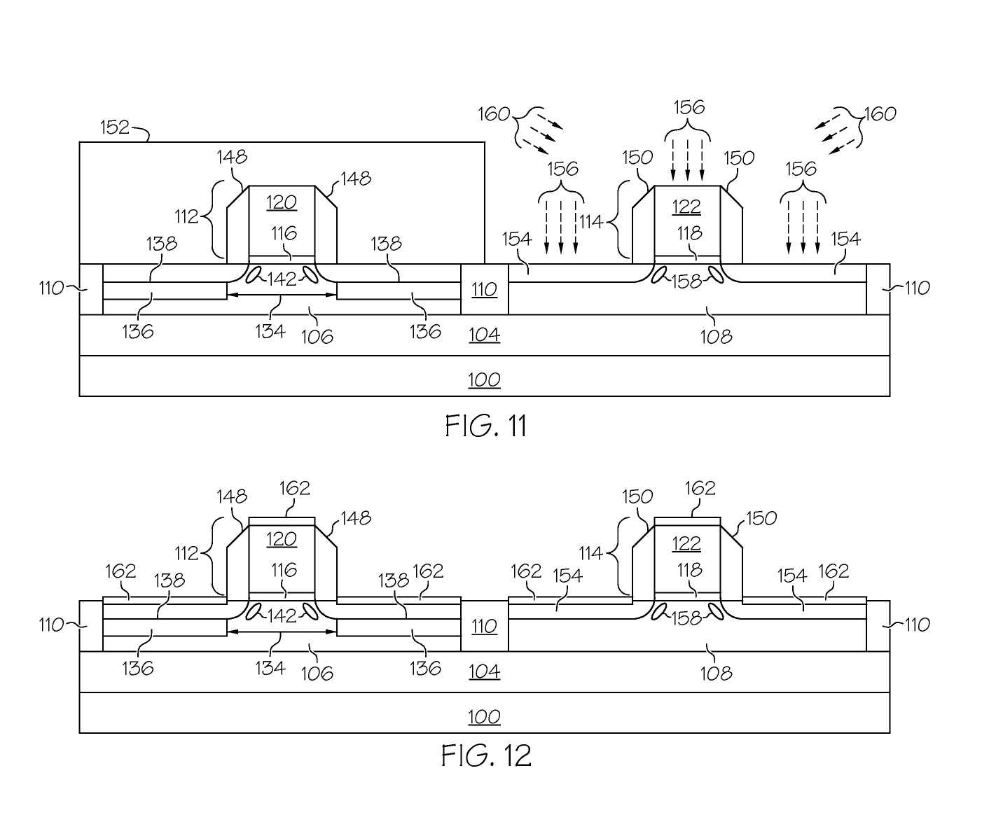

Referring now to FIGS. 9-12, in accordance with one embodiment, a layer of insulating material 146 may be formed overlying the gate electrodes 120, 122, isolated regions 106, 108, and the field oxide 110. In a preferred embodiment, the insulating layer 146 is realized as silicon dioxide (SiO₂) conformally deposited on the semiconductor device in a known manner. In a preferred embodiment, offset spacers 148, 150 are formed adjacent the sidewalls of gate electrodes 120, 122 by anisotropically etching the insulating layer 146, as illustrated in FIG. 10. After formation of offset spacers 148, 150, a layer of photoresist 152 is subsequently applied and patterned to form an implantation mask overlying the first region 106 and gate electrode 120 (i.e., the PMOS transistor) as illustrated in FIG. 11.

In accordance with one embodiment, the fabrication process continues by forming spaced-apart source and drain extensions 154 by appropriately impurity doping the second regions 108 in a known manner, for example, by ion implantation of dopant ions, illustrated by arrows 156, and subsequent thermal annealing. Preferably, the source and drain extensions 154 are formed by implanting ions of a conductivity-determining impurity type into the second region 108 using the gate stack 114, offset spacer 150, photoresist layer 152, and field oxide 110 as an implantation mask. The source and drain extensions 154 are formed in the second region 108 by implanting N-type ions (e.g., arsenic ions or phosphorus ions) into the second region 108 using the photoresist layer 152, the gate electrode 122, and offset spacer 150 as an implantation mask. In this regard, the width of the offset spacers 148, 150 (or the thickness of insulating layer 146) may be tuned as desired for the NMOS source and drain extensions 154 without impacting the source and drain extensions 138 of the PMOS transistor, which are formed without the use of offset spacer 148 in the manner described above. Thus, variation in the offset spacer 148 boundary relative to the boundary of the stressor regions 136 does not affect the amount of P-extension diffusion or lead to corresponding variations in the ensuing PFET source/drain extension overlap, since the cavities 134 and source/drain extensions 140 are defined using spacers 132 and thereby ensuring that the PFET source/drain extension implants are self-aligned to the stressor region, as described above.

In a preferred embodiment, the gate stack 114, spacer 150, photoresist layer 152, and field oxide 110 are also used as an ion implantation mask to form halo implants 158 by appropriately impurity doping the second region 108 in known manner. The halo implants 158 are preferably formed by implanting ions of the same conductivity-determining impurity type as the channel for the second region 108. The halo implants 158 are formed at an angle relative to the surface of the semiconductor device, for example, by ion implantation of dopant ions at an angle, illustrated by arrows 160, and subsequent thermal annealing. The layer of photoresist 152 may be subsequently removed, and the semiconductor device may undergo additional processes, such as deep ion implantation, in a conventional manner. For example, although not illustrated, the second region 108 and gate electrode 122 may be masked with a layer of the photoresist, and deep ion implants may be formed in the first region 106 by implanting P-type ions into the source and drain extensions 138 using the gate stack 112 and offset spacer 148 (or another spacer subsequently formed about sidewalls of gate stack 112) as an implantation mask.

In accordance with one embodiment, contact regions 162 are formed on the gate electrodes 120, 122 and on the isolated regions 106, 108 overlying at least part of the source and drain regions of the respective devices (e.g., source and drain extensions 138, 154), as illustrated in FIG. 12. The contact regions 162 are preferably realized as a metal silicide layer. The contact regions 162 may be formed by depositing a blanket layer of silicide-forming metal onto the surface of the source and drain regions and the surface of the gate electrodes 120, 122 and heated, for example by RTA, to react with exposed silicon and form a metal silicide layer 162 at the top of each of the source and drain regions (e.g., on the stress-inducing semiconductor material 136 and/or semiconductor material 102) as well as on gate electrodes 120, 122. The silicide-forming metal can be, for example, cobalt, nickel, rhenium, ruthenium, or palladium, or alloys thereof and preferably is cobalt, nickel, or nickel plus about 5% platinum. The silicide-forming metal can be deposited, for example, by sputtering to a thickness of about 5-50 nm and preferably to a thickness of about 10 nm. Any silicide-forming metal that is not in contact with exposed silicon, for example the silicide-forming metal that is deposited on the spacers 148, 150 or field oxide 110 does not react during the RTA to form a silicide and may subsequently be removed by wet etching in a H₂O₂/H₂SO₄ or HNO₃/HCl solution.

After formation of the contacts, fabrication of the CMOS device can be completed using any number of known process steps, modules, and techniques. These additional steps are well known and, therefore, will not be described here.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1. A method for fabricating a MOS transistor, the method comprising:
forming a gate stack overlying a layer of semiconductor material;
forming a spacer about sidewalls of the gate stack;
forming cavities in the layer of semiconductor material, the cavities being substantially aligned with the spacer;
forming a stress-inducing semiconductor material in the cavities, wherein the stress-inducing semiconductor material is aligned with outward facing sides of the spacer; and
implanting ions of a first conductivity-determining impurity type into the stress-inducing semiconductor material using the gate stack and the spacer as an implantation mask.

2. The method of claim 1, wherein forming the spacer and forming the cavities comprises:
forming a layer of an insulating material on the gate stack and the layer of semiconductor material; and
etching the layer of the insulating material and the layer of semiconductor material to form the spacer and the cavities, wherein the spacer is formed of the insulating material.

3. (canceled)

4. The method of claim 2, wherein forming a layer of an insulating material on the gate stack and the layer of semiconductor material comprises forming a layer of silicon nitride on the gate stack and the layer of semiconductor material.

5. The method of claim 2, wherein etching the layer of the insulating material and the layer of semiconductor material comprises anisotropically etching the layer of the insulating material and the layer of semiconductor material.

6. The method of claim 1, wherein forming the stress-inducing semiconductor material in the cavities comprises epitaxially growing the stress-inducing semiconductor material in the cavities.

7. (canceled)

8. The method of claim 1, further comprising implanting ions of a second conductivity-determining impurity type into the layer of semiconductor material using the gate stack and the spacer as a second implantation mask to form spaced apart halo implants.

9. The method of claim 1, further comprising:
removing the spacer;
forming a second spacer about sidewalls of the gate stack; and
implanting ions of the first conductivity-determining impurity type into the stress-inducing semiconductor material using the gate stack and the second spacer as a second implantation mask.

10. The method of claim 1, further comprising forming contact regions on the stress-inducing semiconductor material.

11. A method for fabricating a semiconductor device, the method comprising:
forming a gate stack overlying a layer of semiconductor material;
forming a layer of an insulating material on the gate stack and the layer of semiconductor material;
etching the layer of the insulating material and the layer of semiconductor material to form a spacer about sidewalls of the gate stack and cavities in the layer of semiconductor material, the cavities being self-aligned with the spacer;
forming a stress-inducing semiconductor material in the cavities, resulting in stressor regions that are self-aligned with the spacer; and
implanting ions of a conductivity-determining impurity type into the stressor regions using the gate stack and the spacer as an implantation mask.

12. (canceled)

13. The method of claim 11, wherein etching the layer of the insulating material and the layer of semiconductor material comprises anisotropically etching the layer of the insulating material and the layer of semiconductor material.

14. The method of claim 11, wherein implanting ions of a conductivity-determining impurity type into the stressor regions comprises implanting P-type ions into the stressor regions.

15. A method for fabricating a CMOS device, the method comprising:
providing a semiconductor device structure having a first region of semiconductor material and a second region of semiconductor material, a first gate stack overlying the first region of semiconductor material, and a second gate stack overlying the second region of semiconductor material;
masking the second region of semiconductor material; and
while the second region of semiconductor material is masked:
forming a spacer about sidewalls of the first gate stack;
forming cavities in the first region of semiconductor material, the cavities being substantially aligned with the spacer;
at least partially filling the cavities with a stress-inducing semiconductor material, resulting in the stress-inducing semiconductor material being substantially aligned with the spacer; and
implanting P-type ions into the stress-inducing semiconductor material using the first gate stack and the spacer as an implantation mask.

16. The method of claim 15, further comprising forming a layer of an insulating material on the first gate stack and the first region of semiconductor material, wherein forming the spacer about sidewalls of the first gate stack and forming cavities in the first region comprises etching the layer of the insulating material and the first region.

17. The method of claim 16, wherein etching the layer of the insulating material and the first region comprises anisotropically etching the layer of the insulating material and the first region.

18. The method of claim 16, wherein forming the layer of the insulating material comprises forming the layer of the insulating material having a thickness no greater than 20 nm.

19. The method of claim 15, further comprising:
unmasking the second region of semiconductor material;
removing the spacer;
forming offset spacers about sidewalls of the first gate stack and the second gate stack;
masking the first region of semiconductor material; and
while the first region of semiconductor material is masked, implanting n-type ions into the second region of semiconductor material using the offset spacers and the second gate stack as a second implantation mask.

20. The method of claim 15, further comprising:
removing the spacer;
forming a second spacer about sidewalls of the first gate stack; and
implanting P-type ions into the stress-inducing semiconductor material using the first gate stack and the second spacer as a second implantation mask.

21. The method of claim 1, wherein implanting ions of the first conductivity-determining impurity type into the stress-inducing semiconductor material comprises implanting ions of the first conductivity-determining impurity type into the stress-inducing semiconductor material using the gate stack and the spacer as an implantation mask prior to forming a second spacer.

22. The method of claim 1, wherein implanting ions of the first conductivity-determining impurity type results in ion implant boundaries that are self aligned with the spacer and the stress-inducing semiconductor material, such that the spacer controls the proximity to a channel of the MOS transistor for both the stress-inducing semiconductor material and the ion implant boundaries.

23. The method of claim 11, wherein implanting ions of the conductivity-determining impurity type results in source and drain extensions that are self-aligned with the stressor regions, such that the extent of the source and drain extensions depends on the diffusion rate of the ions in the stressor regions.
